(19) United States
(12) Patent Application Publication
(10) Pub. No.: US 2009/0101972 A1
(43) Pub. Date: Apr. 23, 2009

(54) PROCESS FOR FABRICATING A FIELD-EFFECT TRANSISTOR WITH DOPING SEGREGATION USED IN SOURCE AND/OR DRAIN

(76) Inventors: R. Stockton Gaines, Pacific Palisades, CA (US); Yoshio Nishi, Stanford, CA (US); Daniel J. Connelly, San Francisco, CA (US); Paul Clifton, Menlo Park, CA (US)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 12/253,769

(22) Filed: Oct. 17, 2008

Related U.S. Application Data
(60) Provisional application No. 60/980,719, filed on Oct. 17, 2007.

(51) Int. Cl. H01L 21/8238; H01L 23/62

(52) U.S. Cl. 257/335; 438/199; 257/E21.632; 257/E23.001

(57) ABSTRACT

Source and/or drain regions of a transistor are first doped with an appropriate dopant and a metal is subsequently deposited. After heating, a silicide will displace the dopant, creating an increased density of dopants at the border of the silicided region. The dopants that are adjacent to or in the gate region of the device will form a thin layer. The silicide or other reactant material is then removed and replaced with a desired source/drain material, while leaving the layer of dopant immediately adjacent to the newly deposited source/drain material.

### RELATED APPLICATIONS

This is a NON-PROVISIONAL of and claims priority to U.S. Provisional Patent Application No. 60/980,719, filed 17 Oct. 2007, incorporated herein by reference.

### FIELD OF THE INVENTION

The present invention relates to processes for forming insulated-gate field-effect transistors using impurity segregation in one or more sources and/or drains, and replacing the reacted material with one or more other materials.

### BACKGROUND

An insulated gate field-effect transistor (“IGFET”) is a semiconductor-based device in which the charge in one or more channels in one or more semiconductors is controlled by the charge and/or potential at one or more gates, and where the one or more channels are each proximate to one or more source(s) and/or drain(s), wherein a source or drain (“S/D”) is a conducting region providing electrical contact to one or more proximate channels. A semiconductor channel consists of the carriers which are present when the transistor is in one or more typical operating state(s), and which contribute to the conductivity to one or more source(s) and/or drain(s), and which are not present when the transistor is in one or more other typical operating state(s). For example, the semiconductor channel may be located on the opposite side of a gate insulator from a gate, wherein the gate insulator inhibits the transfer of charge directly between one or more gates and one or more channels.

A gate, or gate electrode, is a region, which, at the end of the process, is in a state of relatively high conductivity, and is used to control the charge in one or more channels. Examples of gate materials include heavily doped semiconductors, pure metals, metal-semiconductor compounds such as silicides, and combinations of the foregoing.

An example of a transistor is a device with a single gate, separated from a channel region by a relatively thin insulator, controlling the charge in a single channel in the channel region, comprised of silicon or another semiconductor, wherein the conductance between the channel and a source, and the conductance between the channel and a drain, is used to control the conductance between the source and drain, such that current can either more readily or less readily flow between the source and drain.

Field effect transistors (FETs) may be characterized by the principal carrier type which comprises the one or more channel(s). A FET may be considered an “n-channel FET” (n-FET) if channels are comprised of carriers that exhibit a character of negative charge (“electrons”), while a FET may be considered a “p-channel FET” (p-FET) if channels are comprised of carriers that exhibit a character of positive charge (“holes”). Other FETs may exhibit certain characteristics of both or neither n-FETs and/nor p-FETs, for example ambipolar FETs, or single-electron FETs.

Metal S/D FETs offer the promise of reducing the source and drain resistance relative to a comparable FET with doped S/D. S/D resistance is an increased challenge as devices are thinned, for example as with ultra-thin-body FETs, and therefore while the performance of such devices as fully depleted silicon-on-insulator (FDSOI) FETs and FinFETs may suffer with a doped S/D, a low-resistance metal source and drain may unlock the scaling potential of these alternatives to thick-body technologies such as bulk and partially depleted SOI. An additional advantage is that as device dimensions shrink, controlling the doping profile in a doped S/D FET becomes an increasingly insurmountable problem.

One approach to forming metal S/D FETs is to use a chemical reaction between a deposited metal and the semiconductor to form a metallic compound between the two. For example, see U.S. Pat. No. 6,744,103. Examples of this approach include the reaction of Er and Si to form Er_{1.7}Si for n-FETs (see, e.g., Kedzierski, IEDM 2000, “Complementary silicide source/drain thin-body MOSFETs for the 20 nm gate length regime”), the reaction of Yb and Si to form Yb_{1.7}Si for n-FETs (Zhu, et al., “N-Type Schottky Barrier Source/Drain MOSFET Using Ytterbium Silicide”, IEEE EDL, August 2004), the reaction of Pt and Si to form PtSi (or a related compound) for p-FETs.

A limiting factor in the performance of FETs formed with metal silicides for the source and drain is the Schottky barrier at the source and/or drain. This Schottky barrier is a potential difference between electronic states in the metal and electronic states in the silicon channel. The Schottky barrier reduces the energy available to accelerate carriers in the FET channel, reducing carrier velocity, and reducing net current. An approach to reducing the energy devoted to moving carriers from the source and/or drain into the channel is to induce the carriers to quantum mechanically tunnel between states in the source and/or drain and the channel, rather than investing energy in the carriers sufficiently to “emit” them over the barrier(s). Tunneling occurs with increased probability if the potential profile of the barrier is thinner in the vicinity of the metal/semiconductor contact at the source and/or drain. A greater electric field strength, of the appropriate polarity, normal to the interface generally results in a thinner barrier, and therefore an increased tunneling probability.

One approach to increasing this electric field is to place the metal/channel interface under the gate (see, e.g., Wang, et al., Appl. Phys. Letters, v74, n8, 1999). However, doing so increases device capacitance, increases gate-induced-leakage current, and increases susceptibility to gate length variation (Connelly, et al., IEEE EDL, June 2003). An alternate approach, inducing an electric field via the electrostatic coupling from “side gates” controlled with a separate potential (Parillo, et al., IEEE EDL, October 1991), suffers from increased device complexity, in addition to high capacitance. Using regions of low workfunction metal, electrically connected to the source and drain, reduces the capacitance problem while eliminating the need for additional device connections (Connelly, et al., IEEE TED, January 2006). However, a suitable material selection has yet to be demonstrated.

Doping in the vicinity of the metal/semiconductor interface is another method to increase the electric field. This is, and has been throughout the history of integrated semiconductor devices, widely used at metal/semiconductor contacts. However, the traditional doping method of ion implantation deep into the semiconductor to form a heavily doped region may not be sufficiently controllable.

Recently, devices have been demonstrated in which “doping segregation” is used, for example with NiSi for the source and drain and using arsenic for n-FETs and boron for p-FETs. With this technique, ions are first implanted into Si, then a metal, for example Ni, is deposited, where the Ni is exposed to the Si only in the S/D regions. Next, the Ni is reacted with the Si, forming NiSi. The growth of the NiSi displaces dopant into the Si at the interface, resulting in segregation, or a “snow-plow” effect. The NiSi is then used as the S/D metal, with the doping in proximity to the interface used to increase the electric field at the contact, without a broad enough region of dopant to act itself as a self-contained S/D. Rather, the primary source (and drain) of carriers is the metal, with the dopant acting as an electric-field booster.

This approach results in something of a hybrid between a doped and a metal S/D. While some of the issues of doping control in a doped S/D remain, by bringing the metal intimately close to the channel this process offers the promise of a reduced S/D resistance, especially for ultra-thin-body devices. At the 2006 IEDM, Toshiba showed ultra-thin-body FinFETs fabricated with this method, demonstrating what is likely the highest performance to date for ultra-thin-body FinFETs (see Kinoshita, et al., “Comprehensive Study on Electron Velocity in Dopant-Segregated Schottky MOSFETs”, 2006 IEDM; and Kaneko, et al., “High-Performance FinFET with Dopant-Segregated Schottky Source/Drain”, 2006 IEDM). This approach was earlier disclosed by Koeneke, et al., U.S. Pat. No. 4,485,550.

Dopant segregation has been observed with a variety of metal silicides, with a variety of dopants. For example, M. Wittmer, et al., “The redistribution of metal dopants after metal-silicide formation”, Journal of Applied Physics 49 (12) (1977) report that arsenic tends to segregate at the interface when PtSi or Pd₂Si is formed on Si when the implant dose is at least 2×10¹⁵/cm². Boron has been observed to segregate at a PtSi/Si interface, moving the effective Fermi level at the interface closer to the Si valence band (R. L. Thornton, “Schottky Barrier Elevation by Ion Implantation and Implant Segregation”, Electronic Letters, vol. 17 no. 4, 9 Jul. 1981). Arsenic segregation has also been observed at the reaction front if CoSi₂ and TiSi₂ (Topuria, et al., “Characterization of ultrathin dopant segregation layers in nanoscale metal-oxide-semiconductor field effect transistors using scanning transmission electron microscopy”, Appl. Phys. Lett., vol. 83 no. 21, p. 4433, 24 Nov. 2003).

In U.S. PG PUB 2006-0084232, assigned to the assignee of the present invention, a process was disclosed wherein a chemical reaction is used to define the source and drain region, the byproduct of the reaction is etched away, the resulting recess is filled with one or more metals (possibly after the application of one or more passivation treatment(s)), then the metal(s) are removed from region(s) outside the recess, yielding a self-aligned metal source and/or drain FET.

In U.S. Pat. No. 4,471,524, Kinsbron et al. describe a process is disclosed wherein a “source layer” (such as polycrystalline silicon) with a relatively high concentration of dopants, opposite in polarity to the dopants in the “body”, is formed at source and drain regions, then the “source layer” is reacted (for example, with gaseous oxygen to form SiO₂) such that the dopants segregate into the body material, then contact is made to the body material with a metal (for example, first with an anisotropic etch of SiO₂, then with the deposition of cobalt, then with the application of heat to form CoSi₂, then with the removal of unreacted cobalt). A limitation of the disclosed process is that it fails to remove the reaction product proximate to the channel, and therefore, with a relatively large distance between the S/D material which replaces the reaction product and the channel, the electrical resistance between the these is not minimized.

### SUMMARY OF THE INVENTION

The use of a metal silicide or other reactant product to “snow-plow” dopants to a desired region of a transistor in advance of the reaction front is known. One limitation of the snow-plow approach, as demonstrated to date, is that it requires the selection of a single silicide for both n-FETs and p-FETs. To realize the full potential in a complementary (“CMOS”) process, a separate S/D metal for n-FETs and p-FETs is needed. For n-FETs, a low workfunction metal should be used, while for p-FETs, a high-workfunction metal is needed. One approach is therefore to perform the snow-plow method twice, for example initially for p-FETs, for example with PtSi, which has a relatively high workfunction at its interface with Si, then again for n-FETs, for example using ErSi_{1.7} or YbSi_{1.7}, each of which have a relatively low workfunction at their interface with Si.

This approach, while promising, nevertheless requires two separate silicides, each of which is serving two roles, one to segregate the dopant of the associated type, the other to provide a sufficiently low Schottky barrier interface. An alternate approach is to separate these two functions: use first a material to form a steep doping profile via segregation, then remove the reacted material and replace it with a metal, possibly in conjunction with other materials and/or interfacial passivation, to engineer the workfunction.

Thus, a novel method of exploiting the snow-plow effect is described herein. In brief, the source and drain regions of a transistor are first doped with an appropriate dopant. Then a metal, such as nickel or platinum, is deposited. After heating, a nickel, platinum or other silicide will displace the dopant. In particular, there will be an increased density of dopants at the border of the silicided region. The dopants that are adjacent to or in the gate region of the device will form a thin layer. The silicide or other reactant material is then removed and replaced with the desired source and drain material, while leaving the layer of dopant immediately adjacent to the newly deposited source and/or drain material. This replacement of the metal silicide after dopant migration has not previously been employed in conjunction with the “snow-plow” method.

While the material that replaces the silicide may be silicon or another semiconductor material, of particular interest is the replacement with either a metal or a metal in conjunction with a separation layer in accordance with the methods and systems described in U.S. Pat. Nos. 6,833,556 and 7,084,423, each assigned to the assignee of the present invention. The resulting electrical device may be referred to as an AXFET. The separation layer material enhances device performance, in part by passivating the silicon surface after the removal of the silicide, and by reducing the effect of the Schottky barrier and the Fermi level pinning between the deposited metal and the semiconductor of the body, both of which effects will improve transistor performance compared with a metal/source drain device without the separation layer.

Metal source/drain devices suffer from reduced current due to the Schottky barrier at the metal/semiconductor interface. Doping proximate to a metal/semiconductor contact, for example between a S/D of a FET and its channel, increases the current through that contact, by increasing the degree of tunneling through the potential barrier (“Schottky barrier”) which forms in the semiconductor. Dopant adjacent to the separation layer of an AXFET may also improve the performance of devices using this technology.

By using a chemical reaction to form a localized, relatively high concentration of dopant ions, then replacing the reaction product with one or more other materials, typically including at least one metal, a deposited S/D FET can be fabricated with reduced net “on-state” resistance compared with the resistance without the doping. Using this approach (instead of a more conventional approach such as ion implantation) affords the possibility of realizing many of the advantages of metal S/D or AXFET devices in both bulk silicon and ultra-thin-body FETs, while overcoming the limitations of a Schottky barrier between the metal and the semiconductor channel. It is preferable that the dopant layer should be formed by a process of segregation rather than diffusion such that the dopant layer has a very narrow profile rather than the less abruptly declining distribution typical of a diffusion profile.

It may be advantageous to construct integrated circuits consisting of both n-channel and p-channel devices, but using the above method for only one type of device. A specific example is the use of arsenic for the n-type dopant and boron for the p-type dopant. The source and drain regions are first doped, and then platinum silicide is formed. Platinum silicide will snow-plow both the arsenic and the boron to the desired region in the body of both the n-type and p-type transistors. Platinum silicide has a high work function, which is desirable for p-type devices but not for n-type devices. Next, the platinum silicide is removed from the source and drain regions of the transistors that are intended to be n-type devices, while leaving the platinum silicide in the source and drain regions of the p-type devices. After the removal, a metal or a metal and a separation layer (i.e., an AXFET structure) are deposited. Published data suggest that the p-type devices with a thin boron layer adjacent to the platinum silicide will have good performance. This method, therefore, produces integrated circuits with good performance for both n- and p-type transistors.

The Schottky barrier associated with a replacement metal and a semiconductor in the channel region may be lower if a separation layer is used at their interface. The structure including a separation layer, and a thin layer of doping in the vicinity of the separation layer, is itself an embodiment of the present invention. Other embodiments of the present invention include, but are not limited to a method for forming a field-effect transistor, in which one or more source(s) and/or drain(s) are formed by exposing a semiconductor material containing dopant atoms to a chemical reaction such that the dopant atoms preferentially remain in the semiconductor proximate to the interface between the reaction product and unreacted semiconductor. Examples include a reaction product of nickel silicide, platinum silicide, or other materials that are the basis of the well-know “snowplow”, or “dopant segregation”, effect. Segregating the dopants into a region proximate to the region of the transistor channel (the “snowplow” effect), and subsequently, replacing the reaction product at the source and/or drain. In some cases, the reaction product is replaced, in whole or in part, with one or more metals.

A further embodiment of the present invention provides for forming a FET as above, in which the reaction product is replaced, in whole or in part, with one or more metals, and a separation layer between the metal(s) and the doped semiconductor that remains after the reaction product is removed. The separation layer may serve to passivate the semiconductor surface that remains after the reaction product is removed, and may also beneficially separate the metal(s) from the semiconductor surface to improve the transistor's performance.

Another embodiment of the present invention provides for forming an integrated circuit consisting of n-type transistors constructed in accordance with the processes discussed above and p-type devices consisting of a silicided metal source and drain, in which the same reaction product is formed for both n-type and p-type devices, but the silicided metal is left in place for only one of the device types. A specific example is the use of arsenic for the dopant for the n-type transistors and boron for the dopant for the p-type transistors, and platinum silicide as the reaction product. Platinum silicide will cause dopant segregation for both of these dopants. Though it is possible that even higher performance could be obtained if a separation layer were used for both the p-type and n-type devices, the advantage of adding the separation layer for p-type devices may not be great enough compared with the p-type devices just described without that separation layer to be worth the extra cost and/or complexity of removing the reaction product material (platinum silicide in this example) and replacing it with a separation layer and one or more metals.

A further embodiment of the present invention provides a FET that includes a semiconductor body and one or more metals in the source and drain regions, with the metal immediately adjacent to the semiconductor body having a low work function for n-type transistors and a high work function for p-type transistors, and including both a thin separation layer between the metal(s) and the body, and also a thin layer of dopant in the body immediately adjacent to the separation layer. The separation layer may improve performance compared with devices constructed in the same manner but without such a separation layer. The thin dopant layer may also improve performance compared with similarly constructed devices that do not have this dopant layer, with or without the separation layer.

As should be apparent from the discussion above, one feature of the present invention is that the reaction product is essentially fully removed at the S/D. This allows for one or more of the replacement material(s) to essentially act as the source and/or drain, with the electric field enhanced by the segregated dopants, rather than, as is the case described by Kinsbron, the segregated dopants serving as a source and drain with a subsequent contact made with metal. Further features and advantages of the present invention are discussed in detail below.

### BRIEF DESCRIPTION OF THE DRAWINGS

Embodiments of the present invention are illustrated by way of example in the accompanying drawings, in which:

FIG. 1 shows structures in which: (a) impurities, in this case donor impurities, are placed in the region of the source and drain of a FET, in this example an n-FET; (b) a chemical reaction in the source and drain regions results in segregation of the donor impurities in the region proximate to the edge of the reaction region; and (c) the material resulting from the chemical reaction is replaced with a S/D material.

FIG. 2 shows stages in the formation of a fully depleted silicon-on-insulator structure.

FIG. 3 is a schematic representation of a FinFET process, showing a representative n-FET.

FIG. 4 is a schematic representation of a FinFET process, showing half of a representative N-FET, cut along a plane bisecting the source, gate, and drain.

FIG. 5 is a schematic representation of complementary full-depleted SOI process, where for each illustrated step, an n-FET and a p-FET are shown.

### DESCRIPTION OF THE INVENTION

Discussed herein is a method for forming a FET using impurity segregation in one or more sources and/or drains, and replacing the reacted material with one or more other materials.

In one embodiment of the invention, one or more of the source(s) and/or drain(s) of the FET is formed so that impurities, for example donor impurities for an n-type source and/or drain, or for example acceptor impurities for a p-type source and/or drain, are incorporated into the semiconductor in the region in which one or more source(s) and/or drain(s) is to be formed. For example, ion implantation can be used to cause the impurities to be placed in exposed semiconductor, using a self-aligned process. Or, for example, a layer rich in the desired impurity or impurities may be placed proximate to the semiconductor in the region in which the source(s) and/or drain(s) is to be formed, then heat may be applied to cause the impurity or impurities to diffuse into the proximate semiconductor. Or, for example, a semiconductor containing the impurity or impurities may be directly deposited on exposed semiconductor at the source(s) and/or drain(s) region(s).

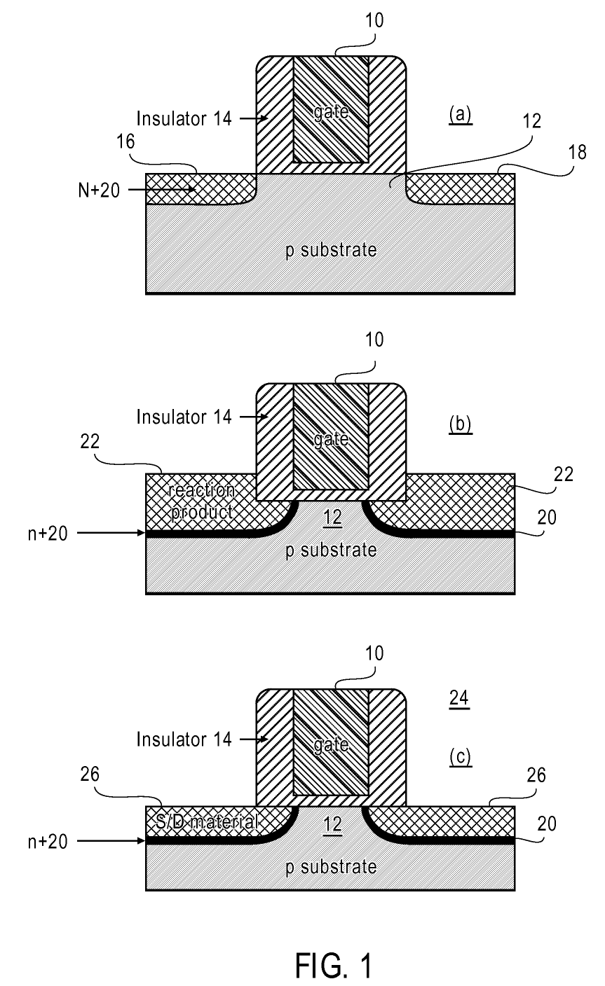

A simplified schematic of an exemplary device structure is shown in illustration (a) of FIG. 1. The gate 10 is separated from the semiconductor forming the channel region 12 by an insulator 14. The semiconductor in the source and drain regions 16, 18 possesses a high concentration of donor impurities 20, which may be either electrically active or electrically inactive, as indicated in the figure by the “n+” labels.

Source and/or drain regions of a semiconductor are made to be exposed, while other regions, for example channel regions and perhaps field regions (field regions being regions in the vicinity of the surface which are neither source, channel, drain, or gate), are not exposed. This exposure may instead be effected prior to the incorporation of ionized impurities, described in the preceding step.

A material, for example metal, is caused to react with the silicon where it is exposed. For example, a metal may be deposited, then the sample heated, in order to promote a reaction between the metal and the exposed semiconductor, where the two are proximate. The reaction is chosen such that it results in the preferential displacement of the impurities into the semiconductor, rather than incorporation of the impurities into the reacted material which displaces the semiconductor. For example, if the semiconductor material is silicon, and the metal is nickel, with the impurities arsenic, it is established that the arsenic tends to “pile-up” on the silicon side of the NiSi/Si interface (see the above-cited Kinoshita and Kaneko references).

Optionally, the reaction may be interrupted, to allow for one or more processes to be carried out before the completion of the reaction. For example, with silicides, a metal-rich silicide may form in the presence of unreacted metal, but if after that reaction has proceeded to a certain point, the unreacted metal is removed, for example via an etch in an HCl solution, the further reaction tends to form a silicon-rich phase. A multi-phase reaction of this type may be preferred, for example for a superior doping profile, or for a superior degree of control, or for a smoother resulting interface.

A simplified schematic of the resulting structure is shown in illustration (b) of FIG. 1. A reaction has occurred in the source and drain regions, causing donor impurities 20 to segregate from the reacted material 22, forming a relatively thin donor-doped region of relatively high donor concentration. These regions are indicated in the figure by “n+”.

In each of the following steps, it may be necessary or desirable to restrict the degree of heating to which the sample is exposed, to limit the degree of ionized impurity diffusion in the proximity of the interface of the reacted material and the unreacted semiconductor. For example long times at elevated temperature may result in a broadening of the distribution of ionized impurities, and with it a corresponding reduction in the peak concentration of ionized impurities.

Further processing may be carried out, for example to facilitate a self-aligned process as described in U.S. PG PUB 2006-0084232, incorporated herein by reference. Eventually the reacted material, for example the product of a reaction between a metal and a semiconductor, is selectively removed, for example via a chemical etchant, leaving one or more recesses.

At the conclusion of this step, it may be preferred that a substantial concentration of the impurities which had been segregated from the reacted material remain. Furthermore, it may be preferred that these impurities exist in a region proximate to the region of the channel 12. Furthermore, it may be preferred that in some region proximate to the channel, these impurities are the dominant contribution to the net impurity concentration of their type (for example, “donor” or “acceptor”).

It should be understood that local impurity concentrations, which is to say the number of impurities in some finite volume, is subject to random variation, and therefore concentration in this context is defined as the concentration averaged over a relatively small volume of an essentially equivalent location of an arbitrarily large (essentially infinite) number of essentially equivalent devices. For example, the average number of impurities in some region of volume 1 nm³ may be 0.05, while over most instances the number may be 0, in fewer (approximately 5%) it may be 1, and in fewer still (approximately 0.3%, perhaps) it may be 2 or more. Yet averaged over a virtual infinity of otherwise equivalent devices in the comparable region, the average will be 0.05 in the 1 nm³ volume, which is to say a concentration of 5×10¹⁹/cm³. As the actual counting of individual impurities over small volumes may be impractical, these expected concentrations can be assessed with the help of numerical physical models, or via the application of models describing observed electrical behavior of the device.

Optionally, one or more passivation steps may be performed with respect to the one or more exposed semiconductor surfaces. In addition, prior or after, other processing may be performed.

In particular, one approach to interface passivation is the use of a “separation layer”, separating a metal from a semiconductor in order to reduce an interaction between the two which may cause a relatively larger Schottky barrier in the semiconductor. For example, in U.S. Pat. No. 6,833,556, assigned to the assignee of the present invention and incorporated herein by reference, a device is described in which passivation, for example with a separation layer, is used to reduce a Schottky barrier between a source and/or drain and a channel. In accordance with the present invention, doping segregation may be used to form a thin doping layer proximate to such a separation layer. The layer of doping should be sufficiently thick to allow for a sufficient electric field, but not so thick that carriers are substantially scattered when traveling between the source/drain material and the channel beyond the doped region. For example, a thickness of 5 nm allows for, at a mean concentration of 10²⁰/cm³, an integrated dose of 5×10¹³/cm², which in Si can boost the interface electric field by approximately 7.6 MV/cm (0.76 V/nm).

One or more metals are placed, for example by conformal deposition, for example via chemical vapor deposition, within the one or more recesses formed by the etching away of the reacted material. These one or more metals may optionally be placed in combination with one or more other materials.

If the placement can be done in a selective fashion, for example via selective chemical vapor deposition, it may be possible to place the one or more metals, possibly in combination with one or more other materials, within one or more recesses while omitting one or more of the metal(s) from one or more regions which are not recesses, or possibly restricting the deposition to a subset of recesses.

Metal may be removed, if present, from one or more regions not within the one or more recesses, leaving metal within the one or more recesses. For example, a sputter etch, or a plasma etch, may be suited to this purpose. The etch may be executed, for example, for a fixed time known to remove the material from without the one or more recesses, while leaving it within the one or more recesses. Or, for example, the etch may use “endpoint detection”, wherein the etch is terminated when a signal, for example chemical or optical, indicates that the metal is adequately removed from without the one or more recesses. Some etches may more readily remove metal from without recesses, while less readily removing metal from within recesses, facilitating the process of removing metal from without the one or more recesses while leaving it within the one or more recesses. For example, sputter etches and plasma etches may be directional in nature, wherein material surfaces with an unobstructed path to a source of ions, for example, are readily etched, while material surfaces with an obstructed path are etched at a substantially slower rate. Etches may be a single step, or may comprise multiple steps, for example an optical endpoint may be used to establish a point at which an “overetch” of fixed duration is applied. Or multiple endpoints may be used, for example.

A simplified schematic of an n-FET 24 fabricated in accordance with an embodiment of the present invention is shown in illustration (c) of FIG. 1. The reacted material in the region of the source and drain has been replaced with a S/D material 26, with the donor impurities 20 still in the semiconductor region proximate to the source and drain.

Further processing steps, for example those described in U.S. PG PUB 2006-0084232 may be used, for example to connect source(s) and/or drain(s), or one or more of previously mentioned steps may be repeated, for the formation of source(s) and/or drain(s) of different characteristics.

Below are described certain exemplar embodiments of the present invention. The strictures include two “ultra-thin-body” field-effect transistors: one a planar, fully-depleted silicon-on-insulator (SOI) metal oxide semiconductor FET (MOSFET), and the other a sidewall-channel FET, or “FinFET”. Finally, an exemplary complementary FET process is disclosed, specifically a complementary fully-depleted SOI process.

In each case certain process steps are schematically represented and described. However, these processes are described in simplified form only. The absence of additional process steps, whether before the listed process sequences, after the listed process sequences, or during the listed process sequences, is not implied. The purpose of these examples is to demonstrate the principles of various embodiments of the present invention, not to fully describe prescriptions for optimal processes.

For example, at present, conventional semiconductor processing provides for strain in the Si in FET channels. This strain can be realized via various means, many well described in the literature. No effort is made in these examples to describe the generation of strain. However, it is understood that the generation of strain may be advantageous, and therefore may be used in conjunction with processes described here.

A Fully-Depicted Field-Effect Transistor.

The first example is of an ultra-thin-body (UTB) fully-depleted (FD) SOI FET. “Ultra-thin-body” in this case corresponds to a device in which alternate current paths to the channel are suppressed by the use of a very, thin semiconductor layer, where the gate is essentially able to control the electrostatic potential throughout the full semiconductor thickness, rather than relying on ionized impurities in the silicon to suppress current paths other than the channel. In this example, a thin Si layer 30 is oriented on an underlying, “buried” SiO₂ layer 32. The density of ionized impurities (dopants) in the thin Si layer should be small, as for very thin layers, the influence of statistical fluctuations in the number of impurities is increased. A particular challenge for UTB FDSOI is reducing the resistance of the source and drain to substantially less than the resistance of the channel. Since metals are typically substantially more conducting than semiconductors doped with even relatively large concentrations of ionized impurities, metal S/D FETs offer the promise of lower source and drain resistance, relative to doped S/D FETs.

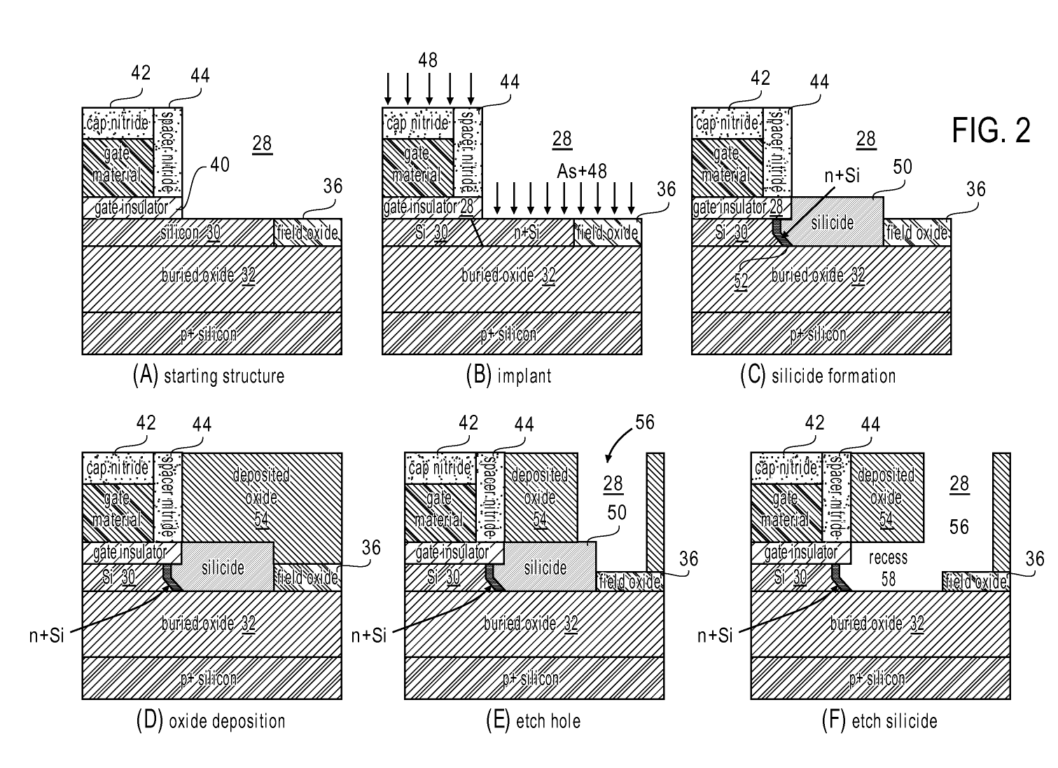

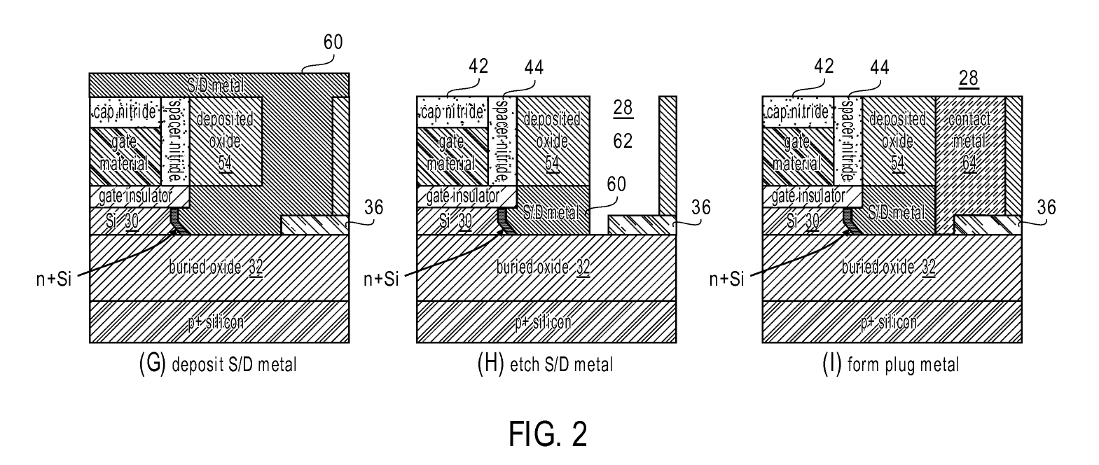

Various process steps for the device 28 are summarized with reference to FIG. 2. Each illustration, (a) through (i), shows a half cross-section of the device, with the half cross-section showing half of a “cut” between the source and the drain perpendicular to a gate. Each cross-section is considered to be symmetric about the left edge. Thus, half the gate 34 is shown, and only one of the source and drain is shown.

Illustration (a) of FIG. 2 shows the starting structure. The cross-section shows an n-FET, although the present invention applies equally well to a p-FET. The silicon region 30 is of sufficiently low impurity concentration that the device operate in a fully-depleted mode, and that the gate(s) can control the potential throughout the underlying silicon. The isolation between devices is achieved via the use of a “field oxide”, indicated at 36 in the figure. The gate 34 is a conductor which may be, for example, a metal, a semi-metal, or a semiconductor which, by the end of the process, will possess a relatively high concentration of ionized impurities such that it exhibits the characteristics of a conductor. The gate is separated from the channel 38 by a gate insulator 40. A cap nitride 42 protects the top of the gate, and the side of the gate is protected by a “spacer nitride” 44. The use of the term “nitride” implies these are formed of Si₃N₄, although one or more other insulators may be used, in combination with or instead of Si₃N₄. The substrate is indicated as p+ Si, although the details of the substrate 46 are unimportant to the present example. Note part of the thin Si layer 30 is exposed. This is the area which corresponds to a source or drain.

Referring to illustration (b) of FIG. 2, the sample is implanted with ionized impurities 48, in this example ionized arsenic (As). These impurities are of sufficient concentration to convert the Si regions to n-type, although they may not yet at this stage in the process be electrically active. The implant is chosen such that the impurities have sufficient energy to penetrate the silicon in the exposed regions, but do not have sufficient energy to penetrate the combination of the gate insulator, the gate material, and the cap nitride. Furthermore, the implant should be substantially blocked by the nitride spacers.

Illustration (c) of FIG. 2 shows the result of silicide formation at the exposed Si. For example, a metal (for example, Pt) is deposited on the surface. The sample is then heated, causing the metal to react with the Si, forming a silicide 50. The unreacted metal is then selectively removed. For example, excess Pt can be removed by aqua regia (see Rand, et al., “Observations on the formation and etching of platinum silicide”, Appl. Phys. Lett., vol. 24, no. 2, pp. 49-51, 15 Jan. 1974). The sample may then be further heated, causing a further expansion of the silicide, with an associated change in stoichiometry. The silicide is chosen such that the ionized impurity (in this example, As) tends to remain in the Si, rather than to incorporate in the silicide. This “snow-plow” effect, or “pile-up”, or “segregation” effect, is shown as an “n+ Si” region 52 adjacent to the edge of the silicide 50.

Illustration (d) of FIG. 2 shows the result of depositing an “oxide” layer 54 and planarizing. The “oxide” may be SiO₂, or some other insulator. The result is that the silicide layer is encapsulated.

Illustration (e) of FIG. 2 shows the result of etching a contact hole 56 to expose a portion of the silicide 50. This may be done with a photolithographic step, in which a mask is used to define the pattern for the hole in a masking layer, for example a photosensitive polymer, or “photoresist”. The process may not be self-aligned relative to the remainder of the structure, and therefore there may be a variation in the position of this contact hole relative to the position of other device features. However, the precise position of the hole may be non-critical, as long as it falls within a suitable range about the nominal position. In particular, the hole needs to expose some portion of the silicide 50, while allowing for the formation of a recess 58 in the following step.

Illustration (f) of FIG. 2 shows the result of etching away the silicide with a selective etch. This etch may be with a liquid-phase species, for example with hot HCl, or in the example of PtSi, with an etch in HF solution followed by a further etch in aqua regia (see Rand, et al., previously cited), or may be with a gas-phase species, for example a reactive species in the vicinity of an energetic plasma. The preferred etch will remove the silicide, without substantially etching the Si, the buried insulator (for example, SiO₂), or the nitride spacer (for example, Si₃N₄).

Illustration (g) of FIG. 2 shows the result of a conformal metal deposition. Some metal depositions are directional. For example, if metal is deposited via sputtering or via evaporation in a relative vacuum, metal particles or ions are caused to traverse along trajectories from a “target” or “source” (in this paragraph, not to be confused with a FET “source”) to the sample. This requires a relatively unoccluded path between the “source” or “target” and the surface on which the metal is to deposit. For a multiplicity, of recesses, it may be impossible or impractical to arrange a sufficient line of sight between one or more “source(s)” or “target(s)” and a sufficient component of the interior of each recess. Thus a method which does not require an unoccluded path is preferred. For example, in certain chemical vapor deposition processes, relatively conformal depositions can be achieved. Chemical vapor deposition may be a preferred method for forming the metal layer 60 required in this step. Chemical vapor deposition can be selective, or non-selective. With a selective process, the deposition occurs preferentially on certain materials. With a selective deposition process, it may be possible to deposit the metal within each recess, without depositing it outside of recesses. The illustrated deposition is non-selective, with deposition occurring both within and without recesses. A selective deposition process, if one is available for the desired metal, may be preferred.

Illustration (h) of FIG. 2 shows the result of removing the metal from regions 62 outside of recesses. For example, an anisotropic etch technique may be used. Anisotropic etching may occur if an electric field is used to accelerate ions in a particular direction, typically relatively normal to the sample surface. Where there is an occlusion, for example in a recess, the energetic ions are relatively blocked, and the etching is relatively less. Thus metal can be etched from regions outside of recesses, while retained from regions within recesses, as illustrated.

Illustration (i) of FIG. 2 shows the result of filling the metal plug with a contact metal 64. It may be desirable to use a different metal for the contact than is used to fill the recess. The metal used to fill the recess must be carefully chosen to achieve a desirably low Schottky barrier to the FET channel, while the contact metal may be chosen based on other criteria, for example chemical stability, low resistivity, electromigration resistance, and other forms of robustness.

Further processing steps, obvious to those skilled in the art of semiconductor processing, can then be carried out to complete the manufacture of circuits. These steps include interconnect metal layer(s) with inter-metal insulating layer(s), and packaging. This device may be combined with other devices in an integrated process. N-FETs and p-FETs can be combined in the same process to make a CMOS process (a CMOS example will follow). Furthermore, multiple types of n-FETs, and/or multiple types of p-FETs, may be fabricated in the same process.

A FinFET Example.

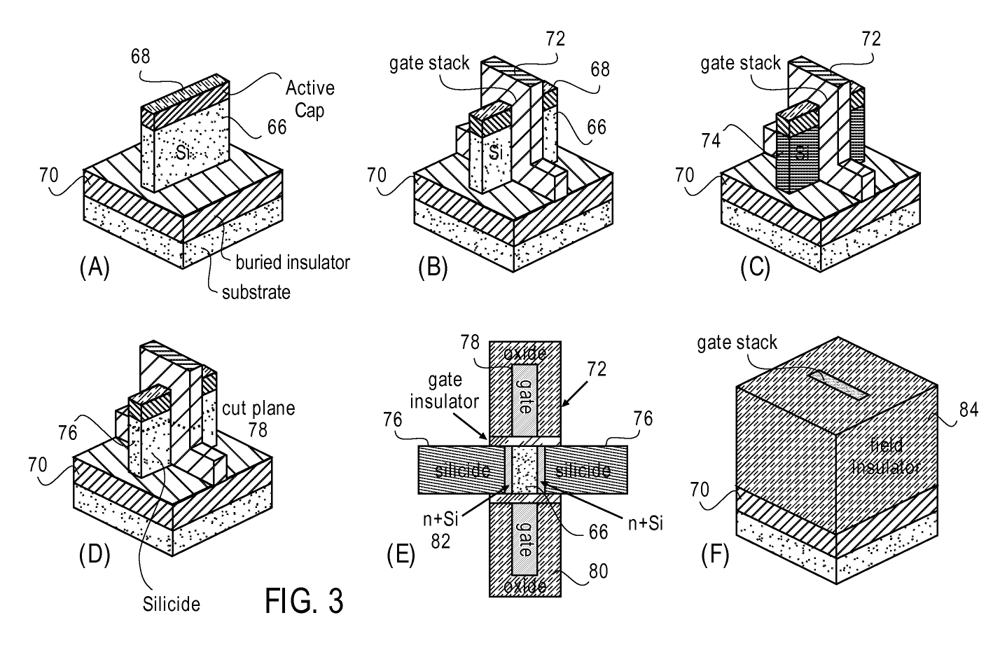

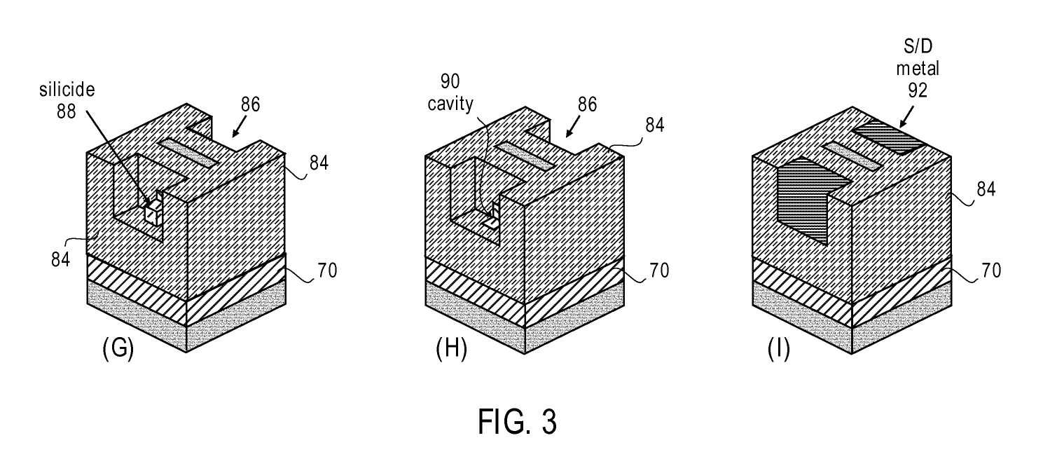

FIG. 3 is a schematic of a process, consistent with the present invention, for creating a FinFET, a field-effect transistor in which one or more gates on either side, and optionally atop, a “fin” of semiconductor, separated from the semiconductor by one or more insulators, are used to control the charge state of the semiconductor comprising the fin.

Illustration (a) of FIG. 3 shows a Si fin 66 capped with a nitride layer 68. The Si fin is on a buried oxide layer 70, although the fin could also be on a silicon substrate, with appropriate process modifications not relevant to the principles of the present invention.

Illustration (b) of FIG. 3 shows the result of forming a gate stack 72. This gate stack consists of several layers. Immediately adjacent to the Si fin is a gate insulator. For example, it may be SiO₂, an alloy of SiO₂, or one or more other insulating materials, perhaps in conjunction with SiO₂. Contacting the gate insulator is one or more, typically one, gate electrode. The gate electrode is encapsulated by insulating materials, for example “spacers” and a “cap” of SiO₂, Si₃N₄, or a combination. The specific details of the gate stack are noncritical to the present invention. Methods of forming such structures are well established in the art. The key factor is that the gate electrode is protected by insulator.

Illustration (c) of FIG. 3 shows the result of applying donor atoms to the region 74 of the Si fin not protected by the gate stack. This can be done via, for example, ion implantation, in which energetic ions of the desired impurity, for example As for an n-FET, or B for a p-FET, are projected towards the fin, typically at multiple angles so each side of the fin is exposed to a trajectory, such that they penetrate the Si fin yet are blocked by the gate stack where that is present.

Illustration (d) of FIG. 3 shows the result of forming a silicide 76 at the regions of the Si fin not covered by the gate stack. For example, Pt may be deposited, then the sample heated in an inert ambient, then the excess Pt removed with aqua regia, leaving PtSi or a related compound of Pt and Si at the location of the uncovered fins. It may be advantageous to etch some of the Si fin prior to depositing the metal, to accommodate the added volume of the compound relative to the Si which is one of its constituents. A dotted line in the figure indicates a plane 78 through which the cross-section from illustration (e) of FIG. 3, which follows, is derived.

Illustration (e) of FIG. 3 shows a cross-section of the structure represented in illustration (d) of FIG. 3. The fins are to the left and right, while the center shows the gate stack 72 and the Si 66 which is covered by the gate stack. The gate electrode is indicated as the “gate” 78. The gate electrode is encapsulated by “oxide” 80 in the figure, which may, for example, be SiO₂. The fins in the region uncovered by the gate stack have been converted to “silicide”, as indicated in the figure, for example PtSi. A region of unreacted Si immediately adjacent to the silicide has been converted to “n+ Si” 82, due to segregation of the dopant which had been placed in the Si fin prior to the silicidation reaction. In this example, the use of As is assumed, where As is a donor in Si, and thus creates “n-type” regions where it is of sufficient concentration were it in a substitutional (electrically active) state.

Illustration (f) of FIG. 3 shows the result of encapsulating the structure from FIG. 3(e) in a “field insulator” 84. For example, SiO₂ may be used. The top of the structure is planar, with the top of the gate stack exposed (for example, a nitride cap on the gate electrode). Whether the gate stack is exposed is non-critical to the process here, however.

Illustration (g) of FIG. 3 shows the result of etching “contact holes” 86 through the encapsulating “field oxide”, exposing a region 88 of the “silicide”.

Illustration (h) of FIG. 3 shows the result of etching away the “silicide”, creating a cavity or recess 90. For example, if the “silicide” is PtSi, it may be etched by first a brief exposure to HF solution (which may partially etch surrounding material, for example SiO₂), then, following, a bath in aqua regia. For other materials, for example other silicides, other etches, for example hot HCl solution, may be preferred.

Illustration (i) of FIG. 3 shows the result of filling the cavity with one or more metals 92, possibly in conjunction with one or more passivation treatments, possibly in conjunction with one or more other materials. Key is that one or more of these depositions be done with a conformal technique, such that they extend into the recess. Exemplary conformal deposition techniques include chemical vapor deposition of LaB₆ from reagents including one or more organometallic compounds, atomic layer deposition, and a passivation process of forming a separation layer by reacting NH₃ with exposed Si (perhaps in conjunction with a plasma). Or, it may be possible to redistribute metal(s) into the cavity with one or more processes after deposition.

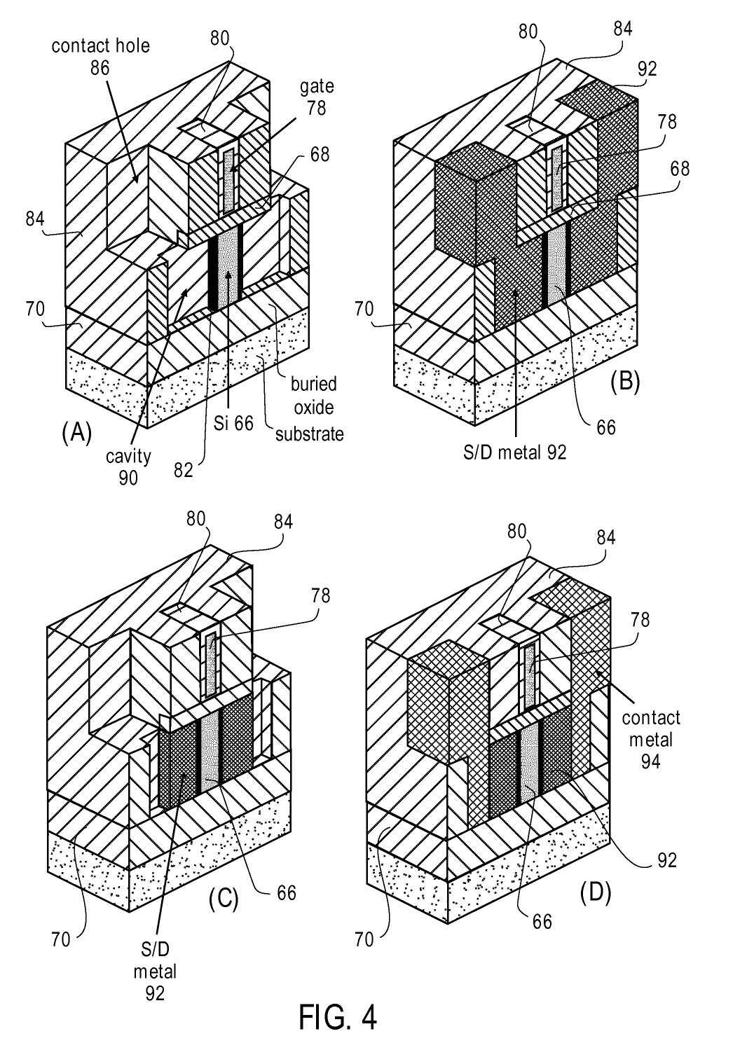

Illustration (a) of FIG. 4 shows an alternate view of the structure from illustration (h) of FIG. 3. Here, the structure from the earlier view is bisected along a symmetry plane, revealing the interior of the cavities 90. Revealed in this drawing is the Si region 66 in which is the body of the transistor. Note the n+ doped regions 82, the result of the doping segregation which resulted from the formation of the “silicide” (at this point the “silicide” has been etched away).

Illustration (b) of FIG. 4 shows an alternate view of the structure from Illustration (i) of FIG. 3. The one or more metals, possibly in conjunction with one or more passivation treatments, possibly in conjunction with one or more other layers, fills the cavity.

Illustration (c) of FIG. 4 shows the result of etching away material(s) in regions not within a recess. The “S/D metal” 92 indicated in the figure, may include one or more metals, possibly in combination with one or more passivation layers, possibly in combination with one or more other materials.

Illustration (d) of FIG. 4 shows the result of the formation of a “contact metal” 94. This metal may be patterned using photolithography, or via one or more other, perhaps self-aligned, processes.

Further processing may be necessary, for example the formation of multiple layers of metal, for the formation of a well-functioning circuit.

A Complementary FDSOI Process.

A complementary field-effect transistor fabrication process (typically called “CMOS”, after “Complementary Metal Oxide Semiconductor”) is one in which both n-FETS and p-FETs are fabricated. Typically n-FETs are used to bring circuit nodes to a lower potential (“pull-down”), while p-FETs bring circuit nodes to higher potential (“pull-up”). Having both n-FETs and p-FETs allows nodes to be brought between lower and higher potentials relatively rapidly.

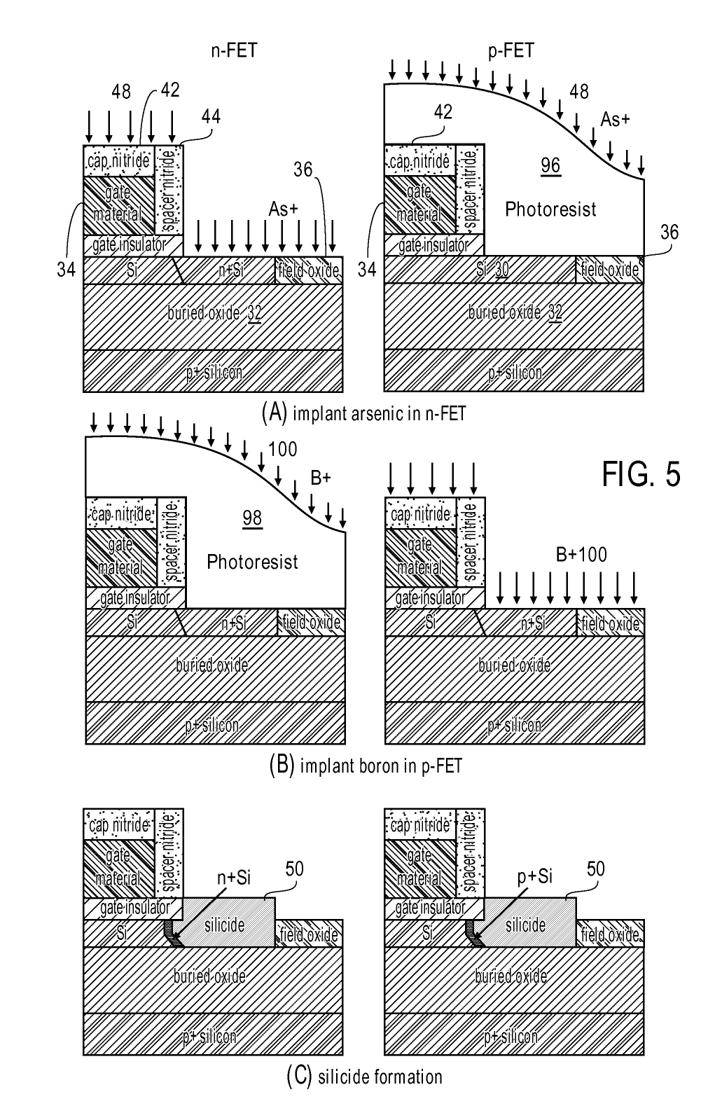

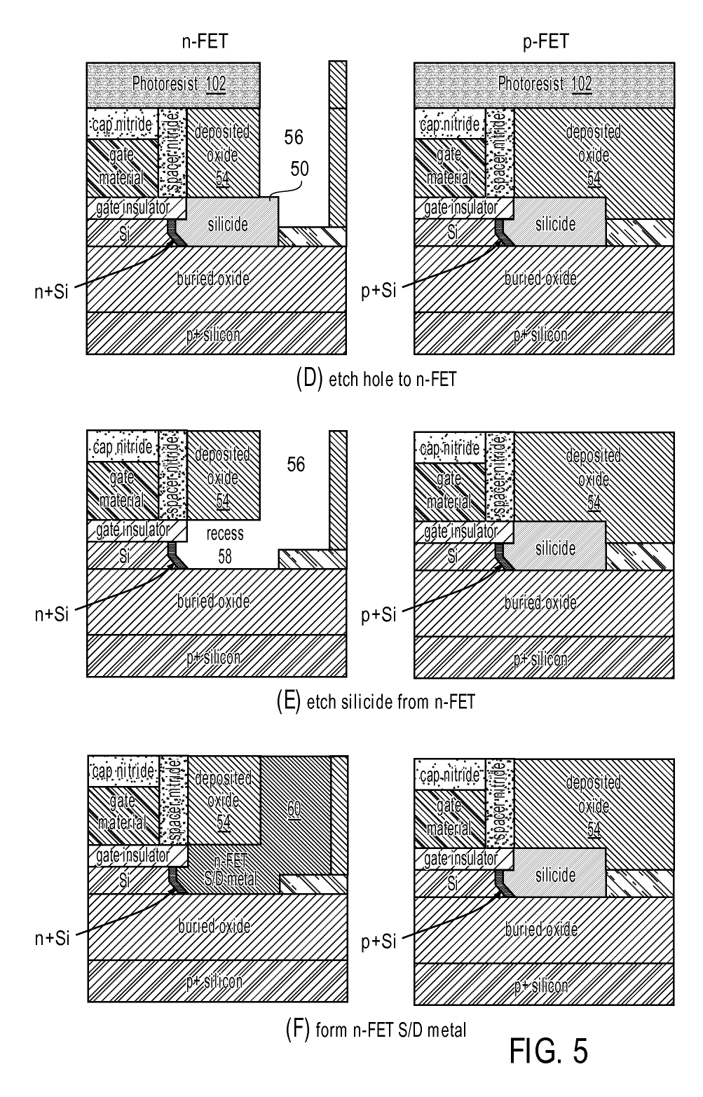

FIG. 5 shows a schematic representation of a complementary FET process exploiting the present invention. In the example, the n-FET is fabricated in accordance with the present invention, while the p-FET uses a silicide source and drain. In each case, both with the n-FET and p-FET, in this example dopant segregation is used to increase the “drive current” capability of the given transistor. However, only in the n-FET is the silicide subsequently replaced, in this example with a metal.

The process shown in FIG. 5 uses fully depleted SOI transistors, similar to the transistors described with respect to FIG. 3. However, the principles described here could as readily be used for forming a complementary process with FinFETs, a device described with respect to FIGS. 3 and 4, or in other devices, for example gate-all-around FETs, planar double-gate FETs, or bulk FETs, or with a combination of devices, for example FinFETs for the p-FETs and fully-depleted SOI for the n-FETs.

For each stage of the process depicted in FIG. 5, both an n-FET and a p-FET transistor are shown, with the n-FET on the left, and the p-FET on the right. It is assumed that these are fabricated in conjunction, for example on the same substrate, and are thus exposed to process steps together.

The starting structure, for both n-FETs and p-FETs, is similar to the structure from illustration (a) of FIG. 2. The text associated with that figure further applies to these structures.

Illustration (a) of FIG. 5 shows a step where charged As ions 48 are accelerated in a trajectory relatively normal to the surface of a substrate. Photoresist 96, and/or perhaps one or more other masking materials, has been used to protect the p-FET from the penetration of these ions. Furthermore, the ions are blocked by the gate stack on the n-FETs. In the source and drain region(s) of the n-FETs, the ions penetrate, turning these source and drain region(s) into regions of a high concentration of As impurities (indicated in the figure as “n+”, although the impurities need not be electrically active at this point in the process).

Illustration (b) of FIG. 5 shows the subsequent removal of the photoresist and/or other masking material(s) from the p-FETs, with the application of photoresist 98 and/or other masking material(s) to the n-FETs, followed by the incidence of one or more beams of ionized boron 100, relatively normal to the surface, such that the boron penetrates the Si in the source and drain region(s) of the p-FETs, but is blocked from penetrating either the channel region(s) of the p-FETs, or any region of the n-FETs. The region(s) in which the boron has penetrated the Si, the source and drain region(s) of the p-FETs, is indicated in the figure as “p+”, even though the impurities may not be electrically active.

Illustration (c) of FIG. 5 shows the result of a silicidation process. After removing the photoresist and/or other masking layer(s) from the structure shown in illustration (b) of FIG. 5, a metal (for example, Pt may be preferred) is applied to the surface. The sample is then heated to facilitate the reaction of Pt with exposed Si, forming, for example, PtSi. This reaction may be carried out in two phases, for example, before and after the removal of unreacted Pt. At some point, either after the completion of the silicide formation 50, or an intermediate point in the silicide formation process, unreacted Pt may be removed without removing the PtSi or related compounds such as Pt₂Si, for example via an etch in aqua regia without exposure to HF (see, for example, Rand, et al., referenced above). The PtSi (or related compound) forms on both the n-FET and p-FET. In the case of the n-FET, arsenic is segregated from the silicide as it grows. In the case of the p-FET, boron is segregated from the silicide as it grows. These segregated ions may be to a large degree electrically active, and thus be to a substantial concentration ionized, and thus form an “n+ Si” region (in the n-FET) and a “p+ Si” region (in the p-FET). Or, sufficient activation may occur with additional processing.

To attain the structure shown in illustration (d) of FIG. 5, first an “oxide” layer 54 is deposited, possibly in combination with a planarization process, to encapsulate the silicide regions. This oxide may be, for example, SiO₂ formed, for example, by a chemical vapor deposition process. Next, photoresist 102 and/or other masking layer(s) is applied and patterned, exposing a region of the oxide above the silicide in the source and drain region(s) of the n-FET, but not the p-FET. Next, a hole 56 is etched in the source and drain region(s) of the n-FET, in areas where the oxide is not protected by the photoresist and/or other masking layer(s). The oxide is etched to the depth of the silicide, exposing it in the n-FET source and drain region(s).

Illustration (e) of FIG. 5 shows the result of etching away the silicide in the source and drain region(s) of the n-FET. It is preferable that this etch remove the silicide and not the surrounding materials. For example, after Rand, et al., previously cited, a brief etch in HF may be necessary if the silicide is PtSi or a related compound, followed by an etch in aqua regia. The HF etch will remove some of the exposed oxide if the oxide comprises SiO₂, for example, and in this instance the initial HF etch should be of sufficiently limited duration that the loss of the oxide is sufficiently restricted. In the p-FET, the silicide remains, as the silicide in the p-FET is not exposed to the etch due to the lack of contact holes at the p-FET source and drain.

Illustration (f) of FIG. 5 shows the result of forming a S/D metal 60 in the regions of the n-FET source and drain(s). This metal may comprise a single metal or as multiple metals. It may comprise, as well, one or more passivation layers, for example a separation layer. It may comprise as well, one or more insulating layers. For example, a preferred embodiment may comprise a plasma nitridation of the exposed Si to form a passivation layer, followed by the deposition of LaB₆ by chemical vapor deposition, followed by a planarization process to restrict the LaB₆ to the recess.

Further processing will be necessary to form fully functional circuits. For example, contacts should be etched to the source and/or drain of one or more p-FET transistors, such that electrical connection can be made to them. Additionally, multiple levels of metal may be formed to connected components of a given transistor, or components of different transistors. Additionally, other devices may be fabricated in addition to the n-FET and p-FET described here.

What is claimed is:

1. A method for forming a source/drain of a field-effect transistor, comprising:
exposing a semiconductor material containing dopant atoms to a chemical reaction such that the dopant atoms preferentially remain in the semiconductor material proximate an interface between a reaction product and unreacted semiconductor material; and
fully replacing the reaction product at the source/drain with another material.

2. The method of claim 1, wherein impurities are segregated into a region proximate a semiconductor channel of the transistor.

3. The method of claim 2, wherein for a given region proximate the semiconductor channel, the segregated impurities represent a majority of dopant impurities.

4. The method of claim 1, wherein the reaction product is replaced, at least in part, with one or more metals.

5. The method of claim 1, wherein the reaction product is replaced, at least in part, with one or more metals in combination with one more passivation treatments.

6. The method of claim 1, wherein the reaction product is replaced, at least in part, with one or more metals in combination with one or more insulating layers.

7. The method of claim 1, wherein the reaction product is replaced, at least in part, by depositing a thin layer, followed by depositing a metal, such that the metal is separated from the semiconductor material by the thin layer.

8. The method of claim 1, wherein when the reaction product is removed, a recess is formed, and wherein said recess is subsequently filled with materials including one or more metals, such that one or more of the metals is proximate a channel region of the transistor.

9. The method of claim 8, wherein one or more of the metals is deposited by chemical vapor deposition such that it preferentially deposits in one or more recesses relative to depositing in regions outside of recesses.

10. The method of claim 8, wherein one or more of the metals is deposited both within recesses and regions not within any recess and wherein the one or more metals are subsequently removed from regions not within any recess, leaving them only within one or more recesses.

11. The method of claim 8, wherein one or more additional metals are subsequently used to contact the metal formed within one or more recesses.

12. The method of claim 1, wherein the reaction product is a result of the chemical reaction between one or more metals and one or more semiconductors.

13. The method of claim 12, wherein the chemical reaction occurs in multiple transistors, and wherein in a first number of the multiple transistors, the reaction product is replaced, while in a second number of the multiple transistors, the reaction product is retained.

14. The method of claim 13, wherein the reaction product in the second number of transistors in which the reaction product is retained is metallic and serves as a source/drain for each of the second number of transistors.

15. The method of claim 14, wherein the reaction product is retained in p-FETs, while the reaction product is replaced in n-FETs.

16. The method of claim 15, wherein the reaction product in contact with the semiconductor material forming the channel region of the p-FETs has an interface with a Fermi level alignment relatively closer to a valence band of the semiconductor material proximate that interface, rather than the conduction band of the semiconductor material.

17. The method of claim 16, wherein the reaction product consists of a compound of Pt and one or more elements of the semiconductor material.

18. The method of claim 17, wherein the chemical reaction is between Pt and Si.

19. The method of claim 15, wherein in source/drain regions of the first number of multiple transistors in which the reaction product is replaced, the reaction product is replaced such that it is proximate an interface with the semiconductor material so that Fermi level alignment is relatively closer to the conduction band of the semiconductor material proximate the interface, rather than to the valence band of the semiconductor material.

20. The method of claim 14, wherein the reaction product is retained in n-FETs, while the reaction product is replaced in p-FETs.

21. The method of claim 20 wherein the reaction product, in contact with the semiconductor material forming the channel region of the n-FETs, has an interface with a Fermi level alignment relatively closer to a conduction band of the semiconductor material proximate the interface, rather than a valence band of the semiconductor material.

22. The method of claim 20, wherein in source/drain regions of the first number of multiple transistors in which the reaction product is replaced, the reaction product is replaced such that it is proximate an interface with the semiconductor material so that Fermi level alignment is relatively closer to a valence band of the semiconductor material proximate the interface, rather than to a conduction band of the semiconductor material.

23. The method of claim 1, wherein the semiconductor is primarily Si, Ge, C; or an alloy of one or more of Si, Ge, and/or C.

24. The method of claim 23, wherein the transistor is an n-channel transistor, and wherein doping impurities include one or more of P, As, and/or Sb.

25. The method of claim 23, wherein the transistor is a p-channel transistor, and wherein doping impurities include one or more of B, Ga, and/or In.

26. The method of claim 12, wherein the chemical reaction results from depositing a metal and subsequently applying heat, causing the metal to react with the semiconductor material.

27. The method of claim 1, wherein the chemical reaction is the result exposing the semiconductor material to a gas and applying heat, causing the semiconductor material to react with the gas.

28. The method of claim 27, wherein the gas contains oxygen, and the reaction product is an oxide.

29. The method of claim 28, wherein the reaction product is primarily SiO₂.

30. The method of claim 1, wherein the reaction product consumes roughly a full thickness of semiconductor material in a region of exposed semiconductor material.

31. The method of claim 30, wherein the semiconductor material is formed on an insulating film.

32. The method of claim 31, wherein the semiconductor material comprises silicon, formed on a layer comprising SiO₂.

33. A field effect transistor, comprising one or more metals in source/drain regions and separated from a semiconductor channel by a separation layer such that electrical current can pass between the one or more metals and the channel region through the separation layer, and wherein proximate the separation layer the semiconductor is doped with a dopant such that a peak concentration of the dopant is approximately coincident with a surface with the separation layer and the concentration of the dopant decreases further from the separation layer, and the channel extends to within 10 nm of the separation layer.
